(19) United States
(12) Patent Application Publication
(10) Pub. No.: US 2026/0369517 A1
(43) Pub. Date: Nov. 19, 2026

(54) Sample Feature Amount Derivation Method, Method for Adjusting Device for Deriving Feature Amounts of Sample, and Measurement System

(71) Applicant: Hitachi High-Tech Corporation, Minato-ku, Tokyo (JP)

(72) Inventors: Kento MAKI, Tokyo (JP); Kazufumi YACHI, Tokyo (JP); Makoto SAKAKIBARA, Tokyo (JP); Kazuo OTSUGA, Tokyo (JP)

(21) Appl. No.: 19/135,637

(22) PCT Filed: Dec. 20, 2022
(86) PCT No.: PCT/JP2022/046763

§ 371 Date: Jun. 4, 2025

(51) Int. Cl. H01J 37/244; H01J 37/22; H01J 37/26; H01J 37/28

(52) U.S. Cl. CPC H01J 37/244; H01J 37/222; H01J 37/265; H01J 37/28; H01J 2237/221; H01J 2237/24495

(57) ABSTRACT

The present invention makes it possible to evaluate characteristics with high accuracy regardless of a temporal change in device condition, machine difference, or the like. To this end, proposed in the present disclosure is a method for deriving feature amounts of a sample on the basis of detection by means of a detector of charged particles obtained on the basis of irradiation of the sample with a beam, wherein the feature amounts corresponding to the amount of the charged particles emitted from the sample are derived by receiving a model which represents an association between output information about the detector and the feature amounts corresponding to the amount of the charged particles emitted from the sample, and by inputting the output information about the detector into the model (see FIG. 2).

### TECHNICAL FIELD

The present disclosure relates to a feature derivation method for a sample, and an adjustment method and a system for an apparatus suitable for feature derivation of a sample, and relates to, for example, a method and a system for deriving a feature based on detection of electrons obtained by irradiating a sample with a charged particle beam.

### BACKGROUND ART

An electron microscope, which is a type of charged particle beam apparatus, is an apparatus that detects, using a detector, secondary electrons obtained by irradiating a sample with an electron beam, and the like. The electrons detected by the detector are converted into an electric signal, and image formation, luminance information derivation, and the like are performed based on the electric signal. PTL 1 discloses that a signal waveform output from a signal processing unit of a scanning electron microscope is calibrated using characteristic data indicating a relationship between a probe current and a gradation value that is prepared according to a gain or an offset of the signal processing unit (see FIG. 12 in PTL 1).

### CITATION LIST

### Patent Literature

PTL 1: JP5777967B

PTL 2: JP6937254B (corresponding U.S. Pat. No. 10,943,762)

### SUMMARY OF INVENTION

### Technical Problem

An output of a detector included in an electron microscope or the like is converted into a luminance signal of an image or the like after a gain and an offset are adjusted by an amplifier provided downstream of the detector output. Generally, the gain and offset adjustment is performed to provide appropriate brightness and contrast across the entire image. On the other hand, there is a method for evaluating electrical characteristics and the like of an evaluation target element by evaluating luminance of a specific element of a semiconductor device or a variation amount of the luminance (see PTL 2). In a case of evaluating the characteristics of the specific element based on luminance information in this manner, when the gain and offset adjustment is performed for the purpose of improving luminance distribution and contrast of the entire image, the luminance of the element changes, and it is considered that it is difficult to appropriately evaluate the characteristics.

In order to stably measure the electrical characteristics and the like, when elements having the same characteristics are irradiated with a beam under the same conditions, it is desirable that the same detector output is obtained even when the beam is emitted at different timings or with different apparatuses, but there is no description in PTLs 1 and 2 regarding such an adjustment of the detector output and a method for correcting the detector output.

In view of such a situation, the disclosure proposes a technique that enables characteristic evaluation to be performed with high accuracy regardless of a temporal change in apparatus condition, a machine difference, or the like.

### Solution to Problem

As one aspect of achieving the above object, the disclosure proposes a method for deriving a feature of a sample based on detection by a detector of charged particles obtained by irradiating a sample with a beam, the method including: receiving a model indicating an association between output information of the detector and a feature corresponding to an amount of the charged particles emitted from the sample, and deriving the feature corresponding to the amount of the charged particles emitted from the sample by inputting the output information of the detector into the model, and a system for implementing the method.

As another aspect of achieving the above object, the disclosure proposes an adjustment method for adjusting a signal processing system that processes an output signal of a detector that detects charged particles obtained by irradiating a sample with a beam, the adjustment method including: receiving, as reference information, associated information between a beam condition and output information of the detector, and adjusting a gain and an offset of the signal processing system using the received reference information, and a system for implementing the method.

Additional features related to the present disclosure will be clarified based on the description of the present description and the accompanying drawings. Aspects of the present disclosure may be achieved and implemented using elements, combinations of various elements, the following detailed description, and accompanying claims.

Descriptions in this specification are merely exemplary, and are not intended to limit the scope of the claims or application of the present disclosure in any sense.

### Advantageous Effects of Invention

According to the technique of the disclosure, a feature by which electrical characteristics and the like can be quantitatively evaluated can be stably acquired.

### BRIEF DESCRIPTION OF DRAWINGS

FIG. 1 is a diagram illustrating a schematic configuration example of an electron microscope 1, which is an example of a charged particle beam apparatus (a charged particle beam system) common to each embodiment.

FIG. 2 is a flowchart illustrating a process of acquiring a secondary electron amount of a sample 1009 based on an appropriate adjustment of a gain and an offset of a detector output according to a first embodiment.

FIG. 3 illustrates an example of a variation curve of the secondary electron amount with respect to a blocking time of a pulsed electron beam with which the sample 1009 is irradiated.

FIG. 4 is a flowchart illustrating a process of correcting a machine difference between apparatuses according to a second embodiment.

FIG. 5 is a flowchart illustrating details of a process of acquiring a relational expression (relationship information) between an electron beam amount and an output signal amount and a target output signal amount described in FIG. 4.

FIG. 6 is a flowchart illustrating details of an adjustment process of a gain and an offset of a second apparatus illustrated in S0403 to S0405 in FIG. 4.

FIG. 7 is a diagram illustrating a configuration example of a measurement and inspection system in which a plurality of electron microscopes are connected to one or more computer systems 7004 via a wired or wireless network.

FIG. 8 is a diagram illustrating a relationship between a beam condition and a detector output.

FIG. 9 is a diagram illustrating a relationship between a first relational expression 9001 of a first apparatus and a second relational expression 9002 of the second apparatus.

### DESCRIPTION OF EMBODIMENTS

In a charged particle beam apparatus, an electron beam irradiation amount with respect to a sample can be changed by setting, but a variation occurs due to instability of beam irradiation. When the beam irradiation fluctuates, an amount of charged particles emitted from the sample also fluctuates, and therefore, in order to derive the emitted charged particle amount, it is necessary to consider not only a detection signal amount and a state of the apparatus but also a beam irradiation amount with respect to the sample. In the following embodiments, a method, a system, and the like for deriving an accurate emitted charged particle amount regardless of a fluctuation in beam irradiation amount or the like will be described.

As a method for solving the above problem, in the present embodiment, relationship information of a detection signal amount with respect to an electron beam irradiation amount is acquired using a reference sample having a known emitted charged particle amount with respect to an electron beam irradiation amount, and relationship information between the emitted charged particle amount and the detection signal amount is derived. For example, when the relationship information between the emitted charged particle amount and the detection signal amount changes due to a machine difference, a temporal change, or the like, a gain and an offset in a signal processing apparatus is adjusted to cancel out the change. Thereafter, an emitted charged particle amount of a sample to be inspected is derived based on the above relationship information between the emitted charged particle amount and the detection signal amount and the detection signal amount of the sample to be inspected.

An influence of hardware changes (a temporal change, an apparatus change, and a probe current fluctuation) is acquired and corrected. A corrected relational expression between the emitted charged particle amount and the detection signal amount is output, and the emitted charged particle amount can be derived by combining the output relational expression and data on the detection signal amount.

Hereinafter, a method for adjusting a charged particle beam apparatus and a charged particle beam apparatus will be described with reference to the accompanying drawings. In particular, a method capable of appropriately evaluating an amount of charged particles emitted from a sample and an amount of charged particles detected by a detector regardless of a machine difference between a plurality of apparatuses or a temporal change of an apparatus, a computer-readable medium storing a program enabling the method, and a system will be described. An electron microscope to be described later is controlled by, for example, one or more computer systems.

### (1) First Embodiment

### <Configuration Example of Charged Particle Beam Apparatus (Charged Particle Beam System)>

A first embodiment discloses a method for acquiring a secondary electron amount of an inspection sample and evaluating characteristics of the sample. In the present embodiment, a secondary electron amount of the inspection sample is acquired, but backscattered electrons generated by irradiation with an electron beam may also be acquired, or a mixed amount of secondary electrons and backscattered electrons may also be acquired.

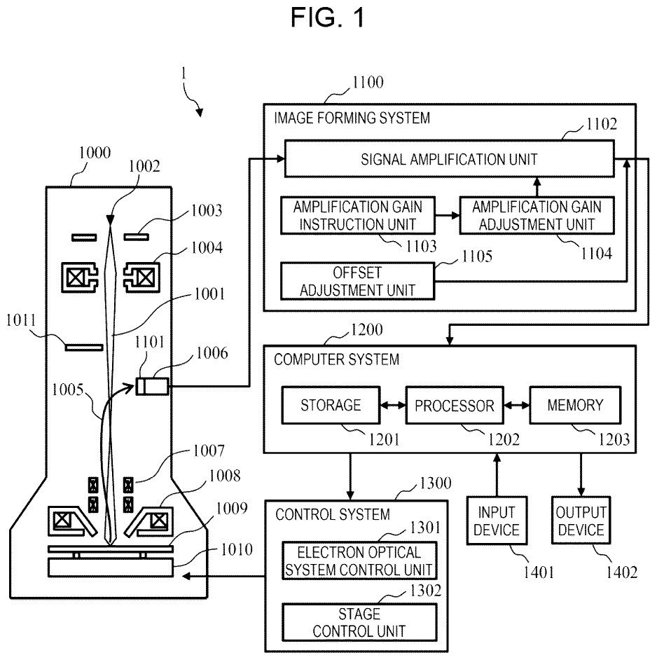

FIG. 1 is a diagram illustrating a schematic configuration example of an electron microscope 1, which is an example of a charged particle beam apparatus (a charged particle beam system) common to each embodiment. The electron microscope 1 is an apparatus that generates an observation image by irradiating a sample with an electron beam. The electron microscope 1 includes a lens barrel unit 1000, an image forming system 1100, a computer system 1200, a control system 1300, an input device 1401, and an output device 1402.

An electron gun 1002 that generates an electron beam 1001 is disposed in the lens barrel unit 1000. The electron beam 1001 is accelerated by an acceleration voltage applied to an acceleration electrode 1003, and is focused by a condenser lens 1004. The electron beam 1001 that passes through the condenser lens 1004 is focused on a sample 1009 by an objective lens 1008. The electron beam 1001 is scanned on the sample 1009 by a deflector 1007. The deflector 1007 scans the electron beam 1001 one-dimensionally or two-dimensionally. Beam deflection by the deflector 1007 may be performed in order to irradiate a desired semiconductor element (a plug or the like) or coordinates with a pinpoint beam. By irradiating the sample 1009 with the electron beam 1001, charged particles (signal electrons 1005) such as secondary electrons and backscattered electrons are emitted from the sample 1009, and the charged particles are detected by the detector 1006. The detector 1006 outputs a detection signal indicating an intensity of the signal electrons 1005.

A stage 1010 has a role of holding the sample 1009 and moving a region to be observed in the sample 1009 to below the electron beam 1001. A beam blocker 1011 is installed in the lens barrel unit 1000, whereby the sample 1009 can be prevented from being irradiated with the electron beam 1001. The beam blocker 1011 may block the electron beam 1001 by inserting an obstacle on a path of the electron beam 1001, or may block the electron beam 1001 by deflecting the electron beam 1001 away from the sample 1009 using at least one of an electric field or a magnetic field.

In order to measure a beam current (Ip) of the electron beam 1001, a Faraday cup (not illustrated) may be disposed in the vicinity of a trajectory of the electron beam 1001, and a beam may enter the Faraday cup to enable measurement of the beam current. For example, the Faraday cup is disposed in the vicinity of a crossover of the electron beam, and can measure the beam current by deflecting the beam toward the Faraday cup by a deflector as necessary.

The image forming system 1100 includes a signal conversion unit 1101 that converts the signal electrons 1005 into an electric signal or the like, and a signal amplification unit 1102 that amplifies the converted signal. An amplification gain of the signal amplification unit 1102 is adjusted by an action of an amplification gain adjustment unit based on an instruction value designated by an amplification gain instruction unit 1103. The image forming system 1100 may also be used to selectively amplify a luminance signal of a particular element, for example, when an image is not being formed. Therefore, in the present description, the image forming system 1100 may be referred to as a signal processing system.

An offset of the signal amplification unit 1102 is adjusted by an offset adjustment unit 1105. Typical examples of the signal conversion unit 1101 include, but are not limited to, a scintillator, a semiconductor detector, a silicon photo multiplier, and a micro channel plate (MCP). The signal amplification unit 1102 is determined by a type of the signal conversion unit 1101. For example, when a scintillator is used as the signal conversion unit 1101, a photo multiplier tube is used as the signal amplification unit 1102. When a semiconductor detector is used as the signal conversion unit 1101, a preamplifier circuit is used as the signal amplification unit 1102. For a silicon photo multiplier tube and an MCP, the signal conversion unit 1101 may also include the signal amplification unit 1102. The instruction value designated by the amplification gain instruction unit 1103 does not necessarily match the amplification gain. For example, for the photo multiplier tube, the instruction value is a voltage value applied to the photo multiplier tube, and the amplification gain has a characteristic of exponentially increasing with respect to the applied voltage.

The computer system 1200 includes a storage 1201, a processor 1202, and a memory 1203. The storage 1201 and the memory 1203 store data used by the processor 1202. The processor 1202 acquires a detection signal of the detector 1006 from the image forming system 1100 and generates an observation image of the sample 1009 using the detection signal. The memory 1203 built in the computer system 1200 is a computer-readable medium, and is a non-transitory computer-readable medium that stores a program instruction executable on the computer system 1200. The computer-readable medium may be a storage medium such as a magnetic or optical disk, a magnetic tape, or any other appropriate non-transitory computer-readable medium known in the technical field. A computer-implemented method may include any step of any of the methods described herein.

The control system 1300 includes an electron optical system control unit 1301 that controls the lens barrel unit 1000, and a stage control unit 1302 that controls an operation of the stage 1010.

In the present embodiment, the electron microscope 1 is exemplified as an example of the charged particle beam apparatus, but the disclosure is not limited thereto, and another charged particle beam apparatus such as a focused ion beam apparatus may be used as an image forming apparatus or a luminance information acquisition apparatus.

The electron microscope 1 is an apparatus that displays, on a display device, a bright and dark image corresponding to an amount of secondary electrons emitted from the sample 1009 by irradiation with the electron beam 1001. Generally, a gain and an offset of an amplifier for amplifying a detector output are adjusted in order to improve an image appearance (an image quality). In an apparatus that performs a measurement and inspection of a semiconductor device, a gain and an offset are adjusted, and the measurement and inspection are performed using an image with clear contrast. For example, a critical dimension scanning electron microscope (CD-SEM) that measures a linewidth of a pattern or the like is an apparatus that enables a highly accurate measurement by adjusting a gain and an offset to accentuate luminance of a portion corresponding to a pattern edge and measuring a distance between luminance peaks.

As described above, in the charged particle beam apparatus that forms an image, a gain and offset adjustment is generally performed with a priority given to an image appearance (a good image quality). On the other hand, when a gain or an offset is adjusted to emphasize a pattern edge or the like, the detector output changes depending on a sample shape or the like in an irradiation region even for the same element (measurement and inspection target).

In the case of evaluating electrical characteristics, material characteristics, or a shape of a semiconductor device by evaluating an amount of charged particles (secondary electrons) emitted from the sample 1009, when a relationship between an amount of charged particles detected by the detector 1006 and the detector output is unstable, the obtained charged particle amount differs even when the same sample is irradiated with a beam under the same condition, and appropriate characteristic evaluation or the like cannot be performed.

Hereinafter, a method and a system capable of performing characteristic evaluation and the like with high accuracy by appropriately maintaining the relationship between the amount of the charged particles emitted from the sample (or a detection amount of the detector) and the detector output regardless of a machine difference, a temporal change, and the like will be described.

### <Analysis of Electrical Characteristics of Sample>

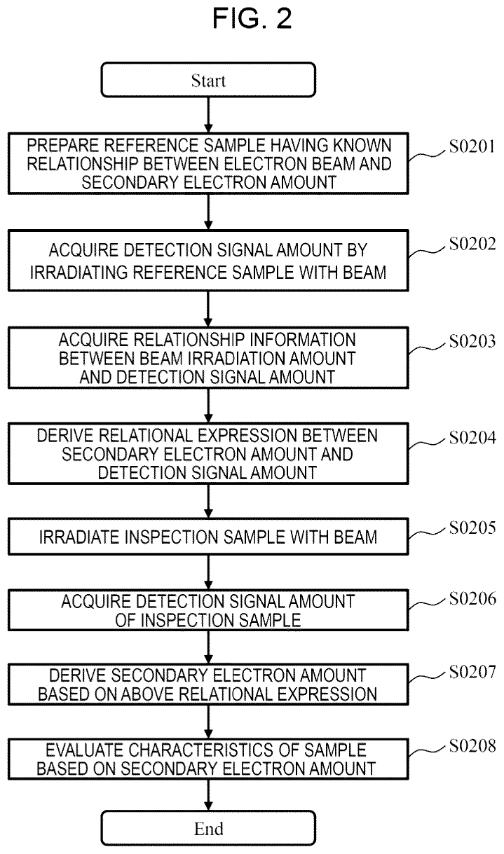

FIG. 2 is a flowchart illustrating a process of acquiring the secondary electron amount of the sample 1009 based on an appropriate adjustment of the gain and the offset of the detector output according to the first embodiment.

### (i) S0201

A user (an operator) prepares a reference sample having a known amount of secondary electrons emitted by irradiation with the electron beam 1001. The reference sample may be a calibration sample having a known secondary electron amount with respect to an electron beam amount that is detected by the detector 1006, or may be a calibration sample having a known ratio between an electron beam irradiation amount and a secondary electron amount.

More specifically, for example, a sample (a reference sample) having a known relationship (γ in an expression (1)) between a beam current (Ip) and a secondary electron amount (Ise) is prepared, and the sample is introduced into a vacuum chamber which is a sample chamber in the electron microscope 1. Such a calibration sample may be placed in advance on a stage in the sample chamber.

Ise=γ×Ip (1)

### (ii) S0202

The computer system 1200 controls the electron microscope 1 in response to a detection signal acquisition instruction (an input by a user) to irradiate the reference sample with the electron beam 1001, and acquires a detection signal amount. When the detection signal is acquired, the detection signal may be used to generate a luminance value of an image or a luminance histogram, or may be waveform data rather than a signal amount. When the detection signal amount is luminance (a gray level: GL), the computer system 1200 acquires, for example, luminance (GL1, GL2) when a beam is emitted under at least two conditions (Ip1, Ip2).

(iii) S0203

The computer system 1200 derives relationship information between a beam condition and the detection signal amount based on the information acquired in S0202 (acquired information). Specifically, the computer system 1200 derives, based on the obtained luminance information and the beam amount, relationship information between the two. For example, the computer system 1200 obtains coefficients such as α and β from the following relational expression (2) by solving simultaneous equations, a regression equation, or the like. The beam condition when acquiring the relationship information may be a plurality of (three or more) conditions, or may include a condition under which no beam is emitted (a GL when Ip=0).

GL=α×Ip+β (2)

### (iv) S0204

The computer system 1200 derives the secondary electron amount and the detection signal amount (Ise-GL relationship information) based on the relationship information between the beam amount and the detection signal amount obtained as described above (for example, Ip-GL relationship information) and relationship information between a beam amount and a secondary electron amount (for example, Ip-Ise relationship information) of the reference sample. For example, the Ise-GL relationship information is expressed by an expression (3).

Ise=γ(GL−β)/α (3)

The above is a process for deriving calibration information of the apparatus. A process for performing actual target measurement and inspection using such calibration information will be described in S0205 to S0208.

### (v) S0205

The computer system 1200 controls the electron microscope 1 to irradiate, with a beam, a predetermined target (for example, a region or a position) of the sample 1009 introduced into the sample chamber. An electron beam condition at this time may be any current amount and irradiation time.

### (vi) S0206

The computer system 1200 acquires a detection signal amount (GL_inspection) under the electron beam condition in S0205. By setting an amplification gain of the amplification gain adjustment unit 1104 and an offset amount of the offset adjustment unit 1105 when acquiring the GL_inspection to be the same as in S0203 (the same as those in the process for deriving the calibration information), calibration based on the calibration information can be performed.

(vii) S0207

The computer system 1200 derives the Ise by substituting the GL_inspection obtained in S0206 into, for example, GL in the expression (3). The computer system 1200 stores the above Ise-GL relationship information for each apparatus condition such as an acceleration voltage of the electron beam, reads the relationship information corresponding to the apparatus condition from the memory 1203, and derives the Ise.

(viii) S0208

The computer system 1200 derives characteristics of the target based on the derived Ise. For example, electrical characteristics of the target can be evaluated by changing a charged state of the sample 1009 by emitting a beam in a pulse shape and gradually increasing a non-irradiation time (a blocking time), and acquiring a variation curve of the signal amount obtained at that time.

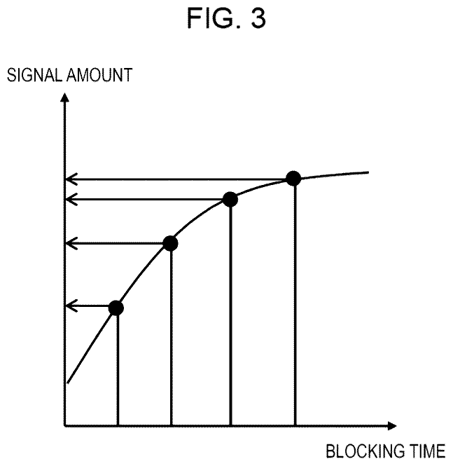

FIG. 3 illustrates an example of a variation curve of the secondary electron amount with respect to the blocking time of a pulsed electron beam with which the sample 1009 is irradiated. The pulsed electron beam is a beam obtained by pulsing the electron beam 1001 emitted from the electron gun 1002. The blocking time is a time between irradiations with the pulsed electron beam. A physical quantity of the electrical characteristics can be derived by fitting the secondary electron amount that changes depending on the blocking time to a simulation result. The characteristic evaluation of the sample is not limited to the electrical characteristics, and a material, a structure, and a shape may be measured and derived.

In addition, it is conceivable to estimate a sample shape by storing associated information between the Ise and a sample shape (such as a hole depth) in advance and substituting the Ise into the associated information. A database indicating an association between the Ise and material information may be created in advance, and the material information may be output by inputting the Ise into the database.

In the first embodiment, the characteristic evaluation is performed based on the secondary electron amount directly indicating the characteristic of the sample, instead of information such as luminance information obtained through the process in the image forming system 1100. Therefore, a stable measurement and inspection result can be obtained regardless of a machine difference between apparatuses and a temporal change of apparatus condition.

In the first embodiment, the relationship information between the beam amount and the detection signal amount is derived using the reference sample, but the disclosure is not limited thereto, and for example, the relationship information between the beam amount and the detection signal amount may be derived based on a detection amount of mirror electrons reflected without reaching the sample or the like by applying a voltage (Vr) higher than an acceleration voltage (Vacc) of the beam to the sample or the stage (|Vr|>|Vacc|) instead of using the reference sample.

The relationship information between the Ise and the GL that is derived through the process illustrated in FIG. 2 is stored in the memory 1203 of the computer system 1200 and used for subsequent inspection or measurement. The computer system 1200 derives the associated information between the secondary electron amount (Ise) and the detection signal amount (GL) using the reference sample, and derives at least one of a secondary electron signal amount, electrical characteristics, material information, and shape information in a depth direction (a Z direction (a beam irradiation direction)) based on the associated information and the detection signal amount obtained from a sample to be measured or inspected.

Here, the electrical characteristics are, for example, resistance or capacitance of an element included in the semiconductor device. By storing the associated information between the Ise and the resistance or capacitance in the memory 1203 in advance, the processor 1202 can derive associated information of the resistance or capacitance based on the associated information and an input (a reception) of the derived Ise. Relationship information between a material type and the Ise may be stored in the memory 1203 in advance, and the processor 1202 may derive information on the material type based on the associated information and the input of the derived Ise.

Further, secondary electrons emitted from a bottom of a deep hole or a deep groove may collide with a side wall of the deep hole or the deep groove. An amount of the colliding secondary electrons increases as the hole or groove becomes deeper. Therefore, relationship information between a depth of a hole or groove and an emitted secondary electron amount is stored in advance in the memory 1203 or the like, and the Ise is substituted into the relationship information, whereby a dimension of the deep hole or deep groove in the Z direction or the like can be derived.

In the first embodiment, the Ise-GL associated information is described as a mathematical model defined in, for example, the expression (3). However, a trained learning model or the like on which training is performed by machine learning may be used. The model may be, for example, a model having an input of output information (a signal intensity, luminance, or the like of a specific pixel) of the detector 1006 and an output of a feature corresponding to the emitted charged particle amount such as an amount of electrons emitted from the sample 1009 or an amount of electrons emitted from the sample 1009 and detected by the detector 1006. The model may be a model having an output of a feature of the sample such as electrical characteristics appropriately corrected based on the Ise-GL associated information.

### (2) Second Embodiment

In the first embodiment, it has been described that a secondary electron amount is acquired based on a detection signal amount of an inspection sample by deriving a relationship between the secondary electron amount (for example, Ise) and the inspection signal amount (for example, GL) when inspecting the inspection sample. However, when analyzing characteristics of a sample by a plurality of apparatuses, since the relationship between the secondary electron amount (Ise) and the detection signal amount (GL) is different for each apparatus, the detection signal amount is saturated under a specific electron beam condition, and a desired secondary electron amount may not be acquired. In the second embodiment, a method will be described in which a relationship between a secondary electron amount serving as an input of a detector and a detection signal amount serving as an output of the detector is made uniform among a plurality of apparatuses.

### <Configuration Example of Inspection System>

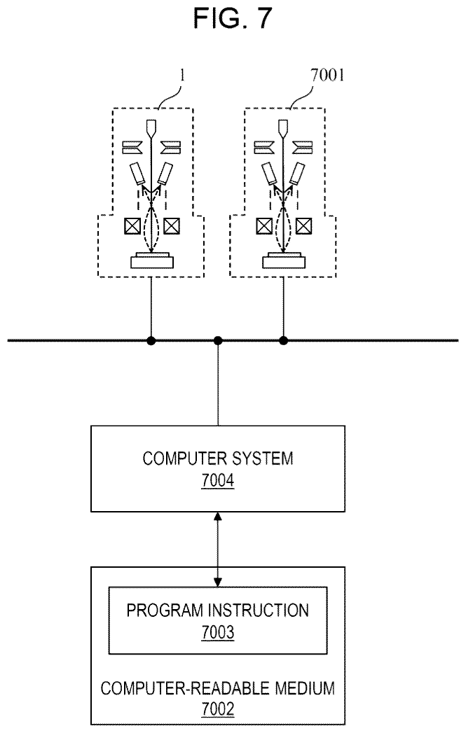

FIG. 7 is a diagram illustrating a configuration example of a measurement and inspection system in which a plurality of electron microscopes are connected to one or more computer systems 7004 via a wired or wireless network. A non-transitory computer-readable medium 7002 includes a program instruction 7003 executable on the computer system 7004. The computer system 7004 processes output information output from the electron microscopes 1 and 7001 in accordance with the program instruction 7003, and transmits necessary information to the electron microscopes 1 and 7001 in accordance with the program instruction 7003. A method executed by a computer may include any step (or a plurality of steps) of any method (or a plurality of methods) described in the present description.

### <Process of Correcting Machine Difference Between Apparatuses>

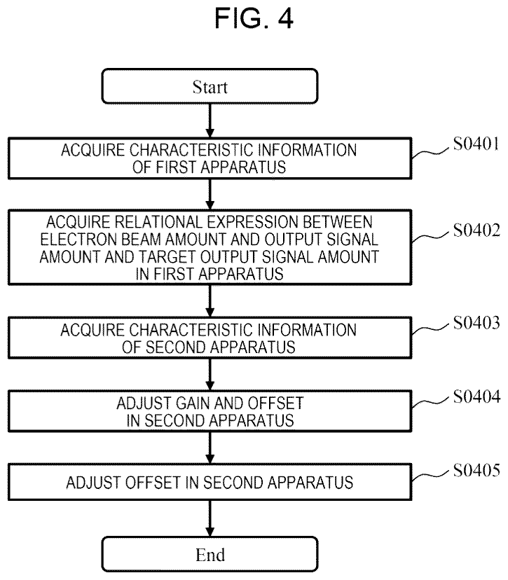

FIG. 4 is a flowchart illustrating a process of correcting a machine difference between apparatuses according to the second embodiment. In the present embodiment, a process of adjusting a gain and an offset such that a change in detection signal amount due to a change in beam condition is consistent will be described. When evaluating characteristics of a sample using luminance information, it is desirable that the same detection signal amount is obtained when a target is irradiated with a beam under the same beam condition, and a change in detection signal amount according to a change in characteristic is also the same. By performing an adjustment through the process illustrated in FIG. 4, an apparatus adjustment suitable for the characteristic evaluation based on luminance measurement can be performed.

### (i) S0401

The computer system 7004 acquires characteristic information of the electron microscope 1 (a first apparatus). A process to be described later may be performed by a computer system (not illustrated) or the like provided in the electron microscope 7001 (a second apparatus) instead of the computer system 7004.

When acquiring the characteristic information, first, a user (an operator) introduces a reference sample into the electron microscope 1. The reference sample is irradiated with the electron beam 1001. The signal electrons 1005 emitted from the reference sample by the beam irradiation are detected by the detector 1006, amplified by the signal amplification unit 1102 via the signal conversion unit 1101, and added by the offset adjustment unit 1105 to obtain an output signal amount.

The characteristic information is, for example, a function indicating a change amount of a detector output (GL) when a beam condition (for example, a beam current) is changed. At this time, characteristic information of the output signal amount can be acquired by acquiring the output signal amount (GL) while changing an electron beam amount (Ip) and an instruction value (a gain value) designated by the amplification gain instruction unit 1103. In this case, the computer system 7004 or the like may derive the characteristic information by obtaining a regression line from a three-dimensional space of the Ip, the gain value, and the GL, for example.

In the present embodiment, the characteristic information of the output signal amount when the electron beam amount and the amplification gain instruction unit 1103 are changed is acquired, but the characteristic information may be derived based on the output signal amount (GL) when another parameter is changed, such as an acceleration voltage set by the electron optical system control unit 1301, an offset amount of the offset adjustment unit 1105, and another adjustment value (adjustment amount) by the control system 1300.

### (ii) S0402

The computer system 7004 acquires a first relational expression between the electron beam amount (Ip) and the output signal (GL) (for example, a function (an Ip-GL characteristic) in which the IP is an independent variable and the GL is a dependent variable) and a first target output signal amount (GL_goal) in the first apparatus.

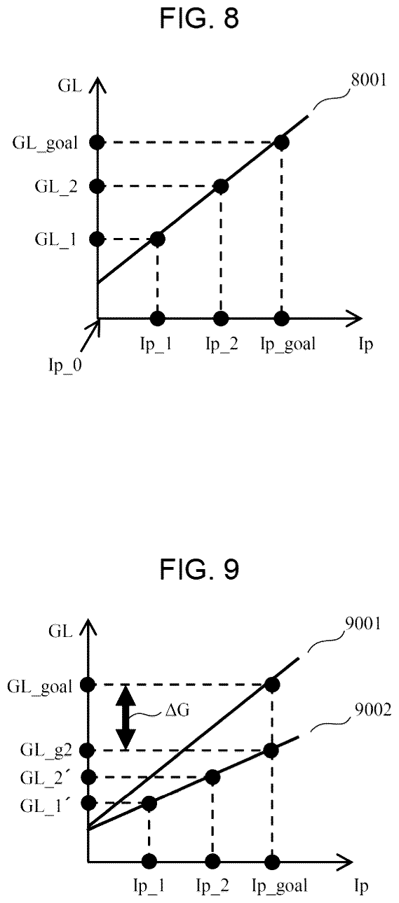

The Ip-GL characteristic is associated information between the beam condition and the output information of the detector. The first relational expression is expressed as illustrated in FIG. 8, for example. The first target output signal amount is detector output information of the first apparatus under a certain beam condition (Ip_goal) at a certain time. A method of acquiring the first relational expression and the first target output signal amount will be further described later.

(iii) S0403

The computer system 7004 acquires characteristic information (an Ip-GL characteristic) of the second apparatus (the electron microscope 7001). A method of acquiring the characteristic information of the second apparatus is the same as the method of acquiring first characteristic information. Here, FIG. 9 is a diagram illustrating a relationship between a first relational expression 9001 of the first apparatus and a second relational expression 9002 of the second apparatus. It can be seen from FIG. 9 that the output signal amount does not become GL_goal even when the beam condition which is one of apparatus conditions in the second apparatus is Ip_goal. That is, when the apparatus is different, the output signal amount may be different even when the beam condition is the same.

Therefore, in the second embodiment, an image forming system of the second apparatus is adjusted such that the output signal amount under a certain apparatus condition is the same among the plurality of apparatuses and the change in output signal amount due to the change in apparatus condition is the same.

### (iv) S0404

The computer system 7004 adjusts a gain and an offset in the image forming system of the electron microscope 7001 such that the first target output signal amount (GL_goal) can be acquired in the second apparatus (the electron microscope 7001). A method of adjusting the gain and the offset will be described later.

### (v) S0405

The computer system 7004 acquires a second relational expression (an Ip-GL characteristic) between the electron beam amount and the output signal amount with the adjusted gain and offset, and stores the information in the computer-readable medium 7002 as the apparatus condition. In the method for obtaining the second relational expression, the second relational expression may be calculated by adding an offset obtained by correcting a difference between the electron beam amount at the time of acquiring the first relational expression and the electron beam amount at the time of acquiring the second relational expression, or may be calculated based on the output signal amount when the electron beam is blocked.

When a relationship of the reference sample between the beam condition (Ip or the like) and the emitted secondary electron amount is known, the computer system 7004 can derive a relational expression between the secondary electron amount and the output signal as in the above-described expression (3).

### <Details of Process of Acquiring Relationship Information and Target Output Signal Amount>

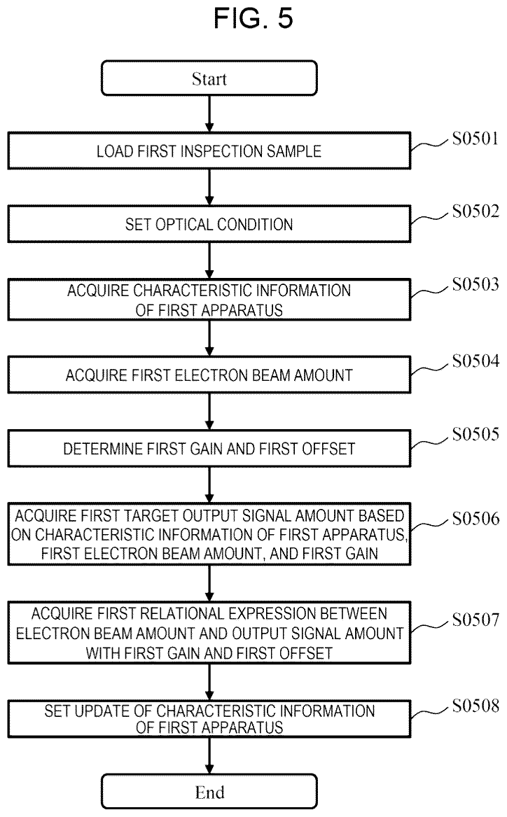

FIG. 5 is a flowchart illustrating details of the process of acquiring the relational expression (the relationship information) between the electron beam amount and the output signal amount and the target output signal amount described in FIG. 4. Hereinafter, each step in FIG. 5 will be described. Here, specific process contents of S0401 and S0402 illustrated in FIG. 4 will be mainly described.

### (i) S0501

When a user (an operator) loads a first inspection sample into the first apparatus (the electron microscope 1) and instructs start of the process, the computer system 7004 activates the control system 1300 and the like to prepare for the start of the process. Here, the first inspection sample is, for example, a sample to be actually measured or inspected.

### (ii) S0502

The computer system 7004 sets an optical condition for acquiring an image of the first inspection sample.

(iii) S0503

The computer system 7004 acquires characteristic information (Ip-GL characteristic information) of the first apparatus. For example, as illustrated in FIG. 8, Ip-GL characteristic information is obtained by deriving at least an inclination (α1) and an intercept (β1) based on two or more Ips (Ip_1 and Ip_2 in the example in FIG. 8) and the corresponding GLs (GL_1 and GL_2). Here, the inclination is a rate of change between the beam condition and the output information of the detector.

### (iv) S0504

The computer system 7004 acquires an actual measured value of the amount of electron beam with which the sample is irradiated. The electron beam amount can be actually measured by actually measuring a beam current using, for example, the Faraday cup described above. Further, the computer system 7004 can derive a difference ΔIp between a set value Ip_s and an actual measured value Ip_a of the beam current and use the difference ΔIp as a correction value when acquiring characteristic information to be described later.

### (v) S0505

The computer system 7004 moves an electron beam irradiation position to a region of interest (for example, a plug electrically connected to an element for evaluating electrical characteristics) of a first sample, and determines a first gain and a first offset. In the gain and offset adjustment, for example, the gain is adjusted such that contrast of the plug becomes clear, and the offset is adjusted such that brightness of the plug becomes appropriate. Here, the gain and the offset may be set by the user or may be automatically set on the computer system 7004.

### (vi) S0506

The computer system 7004 derives the first target output signal amount (GL_goal) based on the characteristic information (the Ip-GL characteristic information) of the first apparatus and the first probe current amount (Ip_goal).

(vii) S0507

For example, the computer system 7004 acquires (calculates) relationship information (a relational expression) represented by the following expression (4) and stores the relationship information in the computer-readable medium 7002.

GL=α1×Ip+β1 (4)

The expression (4) is a relational expression including a coefficient (α1) corresponding to the gain when the first inspection sample is irradiated with the beam and a constant (β1) corresponding to the offset. As illustrated in FIG. 8, the relational expression represented by the expression (4) is obtained by deriving the inclination (α1) and the intercept (β1) based on at least two beam current amounts (Ip_1, Ip_2) and the corresponding luminance information (GL_1, GL_2). A state in which the beam current is zero (Ip_0) may be included. The computer system 7004 can obtain the first relational expression 8001 by solving simultaneous equations and a regression equation.

(viii) S0508

The computer system 7004 determines whether to update the characteristic information acquired before executing the process illustrated in the flowchart in FIG. 5 with newly acquired characteristic information (including a characteristic line or a characteristic curve). Whether to update may be determined based on, for example, a user selection using a GUI (not illustrated). More specifically, a GUI may be prepared that allows the user to select an update cycle, an update time, and the like, and the computer system may perform an update process when a time set by the selection is reached. Additionally, an update may be made in conjunction with an update to a recipe, which is an operating program for operating the electron microscope, or with switching of a sample to be measured. Further, a trend of an output result such as an electrical characteristic may be monitored, and an update may be performed when there is a sudden change or the like.

### <Details of Process of Adjusting Gain and Offset of Second Apparatus>

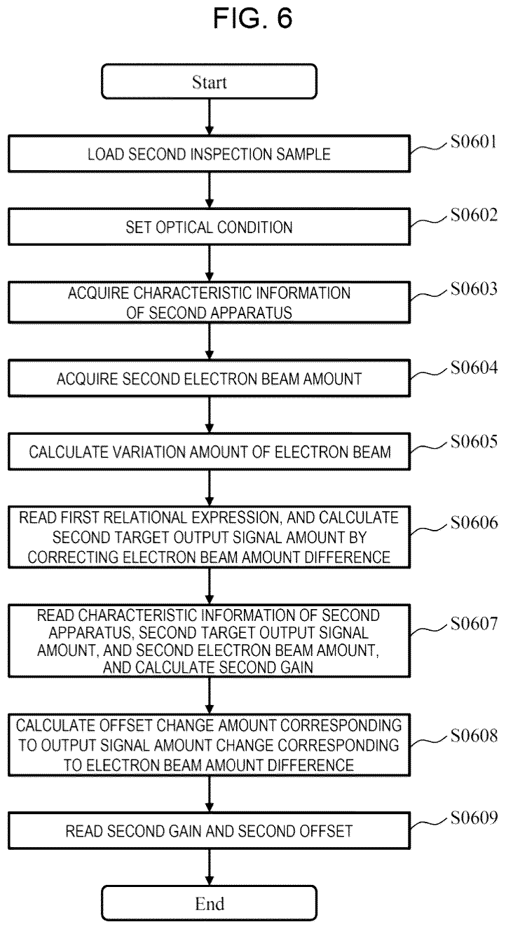

FIG. 6 is a flowchart illustrating details of the process adjusting the gain and the offset of the second apparatus (the electron microscope 7001) illustrated in S0403 to S0405 in FIG. 4.

### (i) S0601

When a user (an operator) loads a second inspection sample into the second apparatus (the electron microscope 7001) and instructs start of the process, the computer system 7004 activates the control system 1300 and the like to prepare for the start of the process. Here, as the second inspection sample, for example, a sample same as the first inspection sample introduced into the first apparatus or a sample having a quality same as that of the first inspection sample can be used.

### (ii) S0602

The computer system 7004 sets an optical condition for acquiring an image of the second inspection sample by the second apparatus (the electron microscope 7001).

(iii) S0603

The computer system 7004 acquires characteristic information (Ip-GL characteristic information) of the second apparatus (the electron microscope 7001). As a reference sample when acquiring the characteristic information of the second apparatus, a first reference sample may be used, or another sample equivalent to (made of a material same as that of) the first reference sample may be used. For example, in order to derive relationship information of the second apparatus (the electron microscope 7001), as illustrated in FIG. 9, the computer system 7004 receives at least two beam current amounts (Ip_1, Ip_2) and luminance information (GL_1′, GL_2′) corresponding thereto from the second apparatus (the electron microscope 7001), and obtains an inclination (α2) and an intercept (β2) thereof. Second relationship information can be defined as, for example, an expression (5), and can be represented as the second relational expression 9002 as illustrated in FIG. 9.

GL=α2×Ip+β2 (5)

### (iv) S0604

The computer system 7004 acquires actual measurement data of the electron beam amount in the second apparatus (the electron microscope 7001). For example, the electron beam amount can be measured using a Faraday cup provided in the electron microscope 7001.

### (v) S0605

The computer system 7004 calculates a variation (ΔIp) in electron beam amount. The variation in electron beam amount can be calculated, for example, by obtaining a difference between a set value and an actual measured value or a difference in beam amount between a plurality of apparatuses when the same set value is set.

### (vi) S0606

For example, the computer system 7004 reads the first relational expression (the Ip-GL characteristic) from the computer-readable medium 7002 and compares the first relational expression with the second relational expression (a relational expression between the electron beam amount and the output signal amount with the adjusted gain and offset: Ip-GL characteristic) to derive a target output signal amount. The target output signal amount is, for example, a GL corresponding to Ip_goal+ΔIp (GL_goal in FIG. 9 when the variation is zero).

(vii) S0607

The computer system 7004 derives a gain adjustment amount based on the target output signal amount (or the difference), the first relational expression, and the second relational expression.

Specifically, the computer system 7004 or the computer system mounted on the electron microscope 7001 derives a gain amount such that, for example, the inclination (α) of the Ip-GL characteristic of the second relational expression 9002 matches that of the first relational expression 8001. The computer system 7004 can also obtain an inclination difference (a gain adjustment amount) by solving simultaneous equations, a regression equation, or the like, as described in the first embodiment.

(viii) S0608

The computer system 7004 or the computer system mounted on the electron microscope 7001 derives a difference (ΔG in FIG. 9 when the variation is zero) in GL corresponding to Ip goal+ΔIp (a specific beam condition) between the first relational expression and the second relational expression. The computer system 7004 or the like derives an offset (bias) amount such that ΔG becomes zero or approaches zero.

### (ix) S0609

The computer system mounted on the electron microscope 7001 reads the derived gain amount and offset amount, and adjusts the gain and offset of the amplifier of the detector output.

### (3) Third Embodiment

In the second embodiment, a gain and an offset are adjusted to obtain the same detection signal between different apparatuses. The same adjustment may be used to adjust a variation in detection signal at different time points in the same apparatus. In the second embodiment, the first apparatus may be read as the same apparatus at a first time point, and the second apparatus may be read as the same apparatus at a second time point.

A timing at which the computer system 1200 acquires characteristic information may be automatically acquired at typical time intervals during which the characteristic information changes over time, or may be acquired at any timing selected by a user.

### (4) Fourth Embodiment

In the first to third embodiments, an example in which an apparatus is calibrated using, as a reference sample (or a standard sample), a sample in which a beam current Ip and an amount of secondary electrons emitted from the sample when the sample is irradiated with a beam of the beam current are known has been mainly described.

On the other hand, an emission amount of secondary electrons varies not only with the beam current Ip but also with other beam conditions such as energy of the electron beam 1001 reaching the sample 1009. Therefore, it is desirable to use, as the reference sample, a sample having a known relationship between a beam condition including a condition other than the beam current and a secondary electron amount.

In a case where a relationship between a certain beam condition and the secondary electron amount is known, a change in detector output (GL) when the certain beam condition is changed may be plotted and a relational expression may be derived to extract associated information between the beam condition and the secondary electron amount.

The signal electrons (secondary electrons) 1005 emitted from the sample 1009 include those that do not reach the detector 1006 due to collision with a structure in the electron microscope 1 after emission. An amount of electrons that are not detected varies depending on an arrangement condition of structures in the electron microscope 1. Therefore, the reference sample having a known relationship between the beam condition and the secondary electron amount (the number of electrons entering the detector) may be used for each structure or type of the apparatus.

Further, when the electron beam 1001 is emitted, a ratio (secondary electron emission efficiency δ) between an amount of secondary electrons emitted from an irradiated portion and an amount of entering electrons depends on the type of material. Therefore, a sample having known secondary electron emission efficiency δ may be used as the reference sample.

The type of the reference sample is not limited as long as the beam condition and the parameter related to the emitted electron amount are known.

### (5) Others

Functions disclosed in each of the above-described embodiments can also be implemented by software program codes. In this case, a storage medium that records the program code is provided in a system or a device, and a computer (or CPU or MPU) of the system or the device reads the program code stored in the storage medium. In this case, the program code read from the storage medium implements the functions of the above-described embodiment, and the program code and the storage medium that stores the program code constitute the present disclosure. Examples of the storage medium for supplying such program codes include a flexible disk, a CD-ROM, a DVD-ROM, a hard disk, an optical disk, a magneto-optical disk, a CD-R, a magnetic tape, a nonvolatile memory card, and a ROM.

An operating system (OS) or the like operating on a computer may perform a part or all of actual processing based on an instruction of the program codes, and the functions of the embodiments described above may be implemented by the processing. Further, after the program codes read from the storage medium are written in a memory on the computer, a CPU or the like of the computer may perform a part or all of actual processing based on an instruction of the program codes, and the functions of the embodiments described above may be implemented by the processing.

The software program codes for implementing the functions of the embodiments may be stored, by distributing via a network, in a storage unit such as a hard disk or a memory of the system or the apparatus or a storage medium such as a CD-RW or a CD-R, and the computer (or CPU or MPU) of the system or the apparatus may read and execute the program codes stored in the storage unit or the storage medium at the time of use.

The process and technique described here are not essentially related to any specific apparatus and can be implemented by a combination of each component. In addition, various types of general-purpose devices can be added. A dedicated apparatus may be constructed to execute the functions of each embodiment. Various functions can be formed by appropriately combining a plurality of components disclosed in each embodiment. For example, some components may be deleted from all the components illustrated in each embodiment, or components in different embodiments may be appropriately combined.

In the disclosure, specific embodiments are described, but these are for description (understanding of the technology of the present disclosure) without limitation in all viewpoints. Those skilled in the art will readily recognize that there are numerous combinations of hardware, software, and firmware that are suitable for implementing the techniques of the present disclosure. For example, the above-described software can be implemented in a wide range of programs or script languages such as assembler, C/C++, perl, Shell, PHP, and Java (registered trademark).

Further, control lines and information lines considered to be necessary for description are shown in the above-described embodiments, and not all control lines and information lines in a product are necessarily shown. All configurations may be connected to one another.

In addition, those skilled in the art can clarify other implementations of the disclosure from consideration of each embodiment. The description and the specific examples are merely typical, and the scope and spirit of the technology of the present disclosure are indicated by the following claims.

### REFERENCE SIGNS LIST

1, 7001 electron microscope
1000 lens barrel unit
1001 electron beam
1002 electron gun
1003 acceleration electrode
1004 condenser lens
1005 signal electron
1006 detector
1007 deflector
1008 objective lens
1009 sample
1010 stage
1011 beam blocker
1100 image forming system
1101 signal conversion unit
1102 signal amplification unit
1103 amplification gain instruction unit
1104 amplification gain adjustment unit
1105 offset adjustment unit
1200, 7004 computer system
1201 storage
1202 processor
1203 memory
1300 control system
1301 electron optical system control unit
1302 stage control unit
1401 input device
1402 output device
7002 computer-readable medium

1. A feature derivation method for deriving a feature of a sample in a computer system based on an output of a detector that detects charged particles obtained by irradiating the sample with a beam, the feature derivation method comprising:
acquiring, by the computer system, a model indicating an association between output information of the detector and a feature corresponding to an amount of the charged particles emitted from the sample; and
deriving, by the computer system, the feature corresponding to the amount of the charged particles emitted from the sample by inputting the output information of the detector into the model.

2. The feature derivation method according to claim 1, wherein
the model is relationship information derived based on the output of the detector when a sample is irradiated with the beam, the sample having a known relationship between a condition for irradiating the sample with the beam and the amount of the charged particles emitted from the sample when the sample is irradiated with the beam under the condition.

3. The feature derivation method according to claim 1, wherein
the model is a mathematical model indicating a relationship between the output information (GL) of the detector and the amount (Ise) of the charged particles emitted from the sample.

4. The feature derivation method according to claim 3, wherein
the computer system generates the model based on the output information (GL) of the detector that is obtained when a reference sample is irradiated with a beam, the reference sample having a known relationship (γ) between a condition (Ip) for the beam and the amount (Ise) of the charged particles emitted from the sample.

5. The feature derivation method according to claim 4, wherein
the computer system generates the model by deriving an unknown number included in a relational expression between a feature corresponding to the charged particles emitted from the sample and the output information of the detector based on the output of the detector that is obtained by irradiating the reference sample with the beam.

6. A measurement system comprising:
a charged particle beam apparatus including a detector that detects charged particles obtained by irradiating a sample with a beam; and
one or more computer systems configured to be communicably coupled to the charged particle beam apparatus, wherein
the computer system executes
a process of acquiring a model indicating an association between output information of the detector and a feature corresponding to an amount of the charged particles emitted from the sample, and
a process of deriving the feature corresponding to the amount of the charged particles emitted from the sample by inputting the output information of the detector into the model.

7. The measurement system according to claim 6, wherein
the model is relationship information derived based on the output of the detector when a sample is irradiated with the beam, the sample having a known relationship between a beam condition for the sample and the amount of the charged particles emitted from the sample when the sample is irradiated with the beam under the beam condition.

8. An adjustment method for adjusting, by a computer system, a signal processing system that processes an output signal of a detector that detects charged particles obtained by irradiating a sample with a beam, the adjustment method comprising:
acquiring, by the computer system, as reference information, associated information between a beam condition and output information of the detector; and
adjusting, by the computer system, a gain and an offset of the signal processing system using the acquired reference information.

9. The adjustment method according to claim 8, wherein
the associated information is a function of the beam condition and the output information of the detector.

10. The adjustment method according to claim 8, wherein
the computer system adjusts the gain to match a rate of change between the beam condition and the output information of the detector in the reference information.

11. The adjustment method according to claim 10, wherein
the computer system adjusts the gain such that a rate of change between the beam condition and the output information of the detector that is obtained by irradiating the sample to be measured with the beam matches the rate of change between the beam condition and the output information of the detector in the reference information.

12. The adjustment method according to claim 8, wherein
the computer system adjusts the offset such that the output information of the detector matches the reference information under a specific beam condition.

13. The adjustment method according to claim 12, wherein
the computer system adjusts the offset such that output information of the detector under the specific beam condition that is obtained by irradiating the sample to be measured with the beam matches the output information of the detector in the reference information.

14. A measurement system comprising:
a detector configured to detect charged particles obtained by irradiating a sample with a beam emitted from a beam source;
a signal processing system configured to process an output of the detector; and
one or more computer systems configured to receive an output of the signal processing system, wherein
the one or more computer systems execute
a process of acquiring, as reference information, associated information between a condition for the beam and output information of the detector, and
a process of causing the signal processing system to adjust a gain and an offset using the acquired reference information.

15. The measurement system according to claim 14, wherein
the associated information is a function of the condition for the beam and the output information of the detector.
